(19) United States
(12) Patent Application Publication
(10) Pub. No.: US 2011/0171913 A1
(43) Pub. Date: Jul. 14, 2011

(54) Frequency Synthesizer

(76) Inventors: Rudolf Bauer, Backnang (DE); Frank Sickinger, Weissach (DE); Thomas Schmidt, Backnang (DE)

(21) Appl. No.: 12/304,679

(22) PCT Filed: Jun. 14, 2006
(86) PCT No.: PCT/EP2006/063226

§ 371 Date: Oct. 27, 2009

(51) Int. Cl. H04B 7/00; H04B 1/04; H04B 1/26; H03L 7/00

(52) U.S. Cl. 455/68; 455/120; 455/196.1; 331/34

(57) ABSTRACT

A frequency synthesizer comprises a tunable oscillator (23) which provides an output signal of the frequency synthesizer, and a sampling phase detector (6) which receives the output signal from oscillator (23) and a reference signal and provides a phase difference signal representative of a phase difference between the output signal and the reference signal, which controls the frequency of the oscillator (23). The frequency of the oscillator (23) is further controlled by a frequency difference signal from a frequency detector (3), which is representative of a frequency difference between the output signal and the reference signal.

### FIELD OF THE INVENTION

The present invention relates to frequency synthesizers for use in wireless communication devices in general and in particular to frequency synthesizers using phase locked loop (PLL) circuits.

### BACKGROUND OF THE INVENTION

It is known to realize such a phase-locked loop by means of a digital phase frequency detector, in which logical circuits are used for comparing output and reference signals. Such a phase-frequency detector may be designed to begin an output pulse whenever an upward zero-crossing of one of its input signals is detected and to stop the output pulse when an upward zero-crossing transition of the other input signal is detected. In this way, an output signal is obtained, the pulses of which have variable widths and distances, if the frequencies of the input signals do not coincide. If the frequencies of the input signals coincide, the output signal is a series of pulses, the frequency of which is equal to that of the input signals and the pulse width of which corresponds to the phase difference between the input signals. If the phases of output and reference signals is equal, the pulse width is 0. The precision with which the equality of phases can be detected is thus limited by the transition times of the logical circuits used.

This disadvantage becomes relevant in particular when the frequency of the output signal is higher than the maximum frequency, which can be processed by the circuits of a conventional digital phase-frequency detector. In order to be able to control such an output signal by means of the conventional phase-frequency detector, a frequency divider must be provided between the output of the oscillator and the corresponding input of the phase-frequency detector, for dividing the frequency of the output signal of the oscillator by a factor N to a frequency which is low enough for the phase-frequency detector to process. According to the present state of the art, this frequency is 200 to 300 MHz maximum. A minimum phase difference ΔΦ, which must exist between the input signals of the phase-frequency detector in order to obtain an output signal impulse of the phase-frequency detector, corresponds to a phase difference NΔΦ at the high output frequency. Therefore, the phase of the oscillator output signal can vary in a substantial range of up to several periods of the oscillator output signal, without the phase-frequency detector being able to detect and correct it. These effects increase the phase noise of the output signal in a phase-locked loop based on the conventional phase-frequency detector.

The problem of non-correctability of small phase variations and the increased phase noise resulting therefrom do not occur in the so-called sampling phase detectors. Their principle of operation is based on sampling the oscillator output signals periodically during predetermined, very short time intervals, which correspond to a certain phase of the reference signal, and to average the sampling values thus obtained. The average values deviate from 0 the more, the further the sampling time is shifted with the respect to a zero-crossing of the oscillator output signal. By controlling the output of the sampling phase detector to be 0, the sampling phase detector may be brought into a locking state in which the phases of output and reference signals are coupled very strictly.

An important feature of the sampling phase detector is that it is capable of locking not only in case of the oscillator output frequency coinciding with the reference frequency, but also if the oscillator output frequency is an arbitrary harmonic of the reference frequency. On the one hand, this is advantageous because it allows to control oscillator output frequencies which may be much higher than the sampling frequency and which, in particular if the sampling phase detector is conventionally formed using an SRD (step recovery diode), may lie in the microwave frequency range, without requiring digital frequency dividers. On the other hand, this also implies that the locking frequency of the oscillator is not unambiguously defined. The sampling phase detector will tune the oscillator to any harmonic of the reference frequency, which happens to be closest to a present output frequency of the oscillator. In order to ensure that the sampling phase detector locks to a desired harmonic of the reference frequency, it must be made sure by design of the tunable oscillator or by circuitry peripheral to it that its output frequency is always close enough to the desired harmonic.

Such a design is generally susceptible to tolerance variations of the employed components. Further, there is a risk that the phase lock loop locks to noise signals close to the oscillator frequency. Locking to a wrong frequency can generally not be detected.

Hence, an improved frequency synthesizer would be advantageous and in particular one, which is tunable in a large frequency range.

### SUMMARY OF THE INVENTION

Accordingly, the invention seeks to preferably mitigate, alleviate or eliminate one or more of the disadvantages mentioned above singly or in any combination.

According to a first aspect of the present invention there is provided a frequency synthesizer as claimed in claim 1.

The frequency synthesizer, according to the first aspect of the present invention comprises a tunable oscillator, which is controlled by a phase-locked loop in order to provide an output signal, the phase and frequency of which are in a predetermined relation to a reference signal.

The frequency synthesizer, comprises a tunable oscillator adapted to provide an output signal of the frequency synthesizer, a sampling phase detector adapted to receive the output signal from the oscillator and a reference signal. The sampling phase detector is further adapted to provide a phase difference signal representative of a phase difference between the output signal and the reference signal for controlling the oscillator. The oscillator is adapted to control its frequency by a frequency difference signal from a frequency detector, which is representative of a frequency difference between the output signal and the reference signal.

Preferably, for combining the two different signals into a control signal for the tunable oscillator, an adder is provided which receives the two different signals and provides a sum signal for controlling the frequency of the oscillator.

In order to prevent control influences of the sampling phase detector and of the frequency detector from disturbing each other at the oscillator in a state in which the frequency of the output signal of the synthesizer is far away from a value adapted to the frequency of the reference signal, the frequency detector is preferably provided with a lock detector circuit for detecting if the frequency difference becomes zero, and the sampling phase detector is adapted to participate in controlling the frequency of the oscillator only if the lock detect circuit detects that the frequency difference is zero.

Such a restriction of the effect of the sampling phase detector can in particular be achieved using an amplifier at a downstream side of the sampling phase detector, the amplification of which is controlled by the lock detect circuit. In such an assembly, the sampling phase detector is free to operate normally, while the frequency detector is not yet locked, so that at the instant at which the frequency difference is detected to be zero, a usable signal from the sampling phase detector is already available.

For generating, based on the reference signal, an output signal with a frequency higher than that of the reference signal, in particular for generating an output signal at a frequency in the microwave range, a first frequency divider is preferably provided, by which the frequency detector receives the output signal. In order to achieve a high frequency division ratio, the first frequency divider may be formed in several stages.

A second frequency divider, by which the frequency detector receives the reference signal, allows obtaining fractional rational-numbered ratios between the frequencies of the reference signal and of the output signal.

In order to prevent the control influences of the sampling phase detector and the frequency detector from disturbing each other when the frequency synthesizer is locked to the desired frequency, the sampling phase detector may be designed to react more quickly than the frequency detector to a drifting apart of the phases of output signal and reference signal.

In case that the sampling phase detector and the frequency detector each comprises a filter for filtering the phase difference signal and the frequency difference signal, respectively, such different reaction speeds may be achieved by the filter of the sampling phase detector having a higher bandwidth than that of the filter of the frequency detector.

According to a second aspect of the present invention there is provided a radio transmitter as claimed in claim 9.

The radio transmitter, according to the second aspect of the present invention, comprises a frequency synthesizer including a tunable oscillator adapted to provide an output signal of the frequency synthesizer, a sampling phase detector adapted to receive the output signal from the oscillator and a reference signal. The sampling phase detector is further adapted to provide a phase difference signal representative of a phase difference between the output signal and the reference signal for controlling the oscillator. The oscillator is adapted to control its frequency by a frequency difference signal from a frequency detector, which is representative of a frequency difference between the output signal and the reference signal.

According to a third aspect of the present invention there is provided a radio receiver as claimed in claim 17.

The radio receiver, according to the third aspect of the present invention, comprises a frequency synthesizer including a tunable oscillator adapted to provide an output signal of the frequency synthesizer, a sampling phase detector adapted to receive the output signal from the oscillator and a reference signal. The sampling phase detector is further adapted to provide a phase difference signal representative of a phase difference between the output signal and the reference signal for controlling the oscillator. The oscillator is adapted to control its frequency by a frequency difference signal from a frequency detector, which is representative of a frequency difference between the output signal and the reference signal.

According to a fourth aspect of the present invention there is provided a method of operating a frequency synthesizer as claimed in claim 25.

The method of operating a frequency synthesizer in a wireless communications unit, according to the fourth aspect of the present invention, comprises the step of generating an output signal of the frequency synthesizer by a tunable oscillator and receiving the output signal by a sampling phase detector and by a frequency detector. The sampling phase detector and the frequency detector also receive a reference signal. The sampling phase detector provides a phase difference signal representative of a phase difference between the output signal and the reference signal and the frequency detector provides a frequency difference signal representative of a frequency difference between the output signal and the reference signal. In the final step the phase and frequency of the oscillator are controlled by the phase difference signal received from the sampling phase detector and by the frequency difference signal received from the frequency detector.

Further features of the present invention are as claimed in the dependent claims.

The present invention beneficially allows for providing a tunable frequency synthesizer, which is tunable in a large frequency range that may comprise several harmonics of a reference frequency, and which is capable of locking with little phase noise to a desired one among these harmonics. The invention can be beneficially implemented in transmit and receive parts of wireless communication devices. It can be used both in fixed radio systems as well as in mobile radio devices.

### BRIEF DESCRIPTION OF THE DRAWINGS

The present invention will be understood and appreciated more fully from the subsequent description of embodiments thereof referring to the appended drawings in which:

FIG. 1 is a block diagram of a frequency synthesizer according to the invention;

FIG. 2 is a schematic circuit diagram of a sampling phase detector which can be used in the frequency synthesizer of FIG. 1; and

FIG. 3 is a schematic circuit diagram of frequency detector, which can be used in the frequency synthesizer.

### DESCRIPTION OF AN EMBODIMENT OF THE INVENTION

The present invention is discussed herein below in the context of a frequency synthesizer. However, it should be understood that it is not limited thereto, but instead applies to any wireless communications device, whether fixed or mobile, using a frequency synthesizer as described above in its transmit or receive part as well as to a method of operating such a frequency synthesizer.

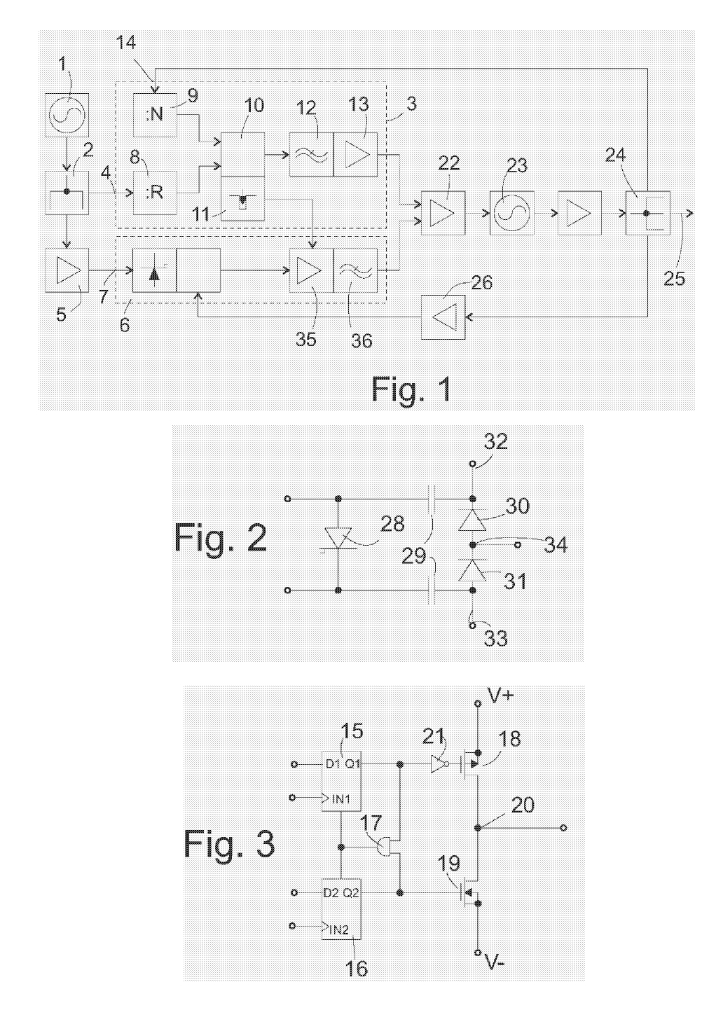

In the block diagram of FIG. 1, a source for a reference signal is referred to by 1. The source 1 is not regarded as part of the frequency synthesizer and can be of any type. The reference signal is applied to a reference input 4 of a frequency detector block 3 via a signal divider 2 and to a reference input 7 of a phase detector block 6, eventually via an amplifier 5.

The frequency detector block 3 comprises programmable frequency dividers 8, 9, a phase-frequency detector 10, a lock detection circuit 11, a loop filter 12 and an output amplifier 13. An input of the frequency divider 8 is directly connected to the reference input 4, an input of frequency divider 9 is connected to a feedback input 14. The frequency dividers 8, 9 are designed as digital counters and provide the reference signal and a feedback signal applied to a feedback input 14, frequency-divided by a programmed factor R or N, respectively, to the phase-frequency detector 10.

Phase-frequency detectors are known as such in numerous embodiments, so that for the purpose of the present description, the operation of the phase-frequency detector 10 will only be outlined briefly based on schematic FIG. 3.

The phase-frequency detector 10 comprises two D-flip-flops 15, 16, the D inputs of which D1, D2 are constantly held on logical level 1. A trigger input IN1 of flip-flop 15 is connected to the output of frequency divider 8 and a trigger input IN2 of flip-flop 16 is connected to the output of frequency divider 9. It is assumed that the flip-flops 15, 16 are each triggered by a rising flank of the signals at trigger inputs of IN1 and IN2, respectively, to store the logical level present at its data input D1, D2, respectively, and to output it at a data output Q1, Q2, respectively. The data outputs Q1, Q2 of the flip-flops 15, 16 are fed back to clear inputs CLR1, CLR2 of the two flip-flops 15, 16 via an AND gate 17. Two switches, represented here as FETs 18, 19, are connected in series between a positive supply potential V+ and a negative supply potential V-. A node between the two switches 18, 19 forms an output 20 of phase-frequency detector 10. A control input of FET 18 is connected to data output Q1 of flip-flop 15 via an inverter 21, and a control input of FET 19 is directly connected to data output Q2 of flip-flop 16.

Together, the two flip-flops 15, 16 can assume three stationary states, namely:
Q1=Q2=0: in this state, both FETs 18, 19 are non conductive and output 20 is highly resistive;
Q1=1, Q2=0: FET 18 is conductive, FET 19 is non conductive, and a charge is flowing from V+ to output 20; and
Q1=0, Q2=1: FET 18 is non conductive, FET 19 is conductive, and a charge is flowing from output 20 to V-.
The state Q1=Q2=1 is excluded by AND gate 17.

If it is assumed that the frequency of the reference signal at input IN1 is higher than that of the feedback signal at input IN2 of the flip-flop 15, 16, this implies that flip-flop 15 is triggered more frequently than flip-flop 16, and, in consequence, that in the average FET 18 is conductive for a longer time than FET 19. Conversely, FET 19 is conductive for a longer time if the frequency at input IN1 is lower than at input IN2.

If the frequencies at inputs IN1, IN2 coincide, the phase-frequency detector 10 provides current pulses at output 20 at a frequency similar to the frequencies at the inputs, the duration and the sign of the pulses being dependent on the phase relationship of the signals at the inputs IN1, IN2.

The lock detection circuit 11 can take advantage of this effect by detecting that the frequencies coincide if a predetermined number of consecutive current pulses having the same sign or a width not exceeding a predetermined limit was output at output terminal 20.

The loop filter 12 comprises an integrator, in the simplest case a capacitor, which integrates the currents from output 20 of the phase-frequency detector 10 and outputs a voltage level proportional to the integral, and, eventually, a low-pass filter having a limit frequency below the frequencies of the signals at the inputs IN1, IN2, in order to suppress a residual oscillation of the integral.

The filtered integral output by loop filter 12 controls a voltage-controlled oscillator 23 via an adder 22. Via a signal divider 24, the oscillation generated by a oscillator 23 reaches the output 25 of the frequency synthesizer and the input of frequency divider 9.

FIG. 2 schematically shows the structure of an upstream portion of phase detector block 6. A step recovery diode 28 is supplied with the reference oscillation from source 1 amplified by amplifier 5. When the current direction of the reference oscillation becomes the blocking direction of diode 28, the latter very quickly stops the current, and a voltage pulse resulting therefrom is transmitted via capacitors 29 to two diodes 30, 31, which are connected in series and are supplied with the oscillation of voltage controlled oscillator 23 at terminals 32, 33 via an amplifier 26. The voltage pulse caused by step recovery diode 28, which is polarized in the transmission direction of diodes 30, 31, causes a sampling value of the oscillation of oscillator 23 to be present at a junction node 34 between the diodes 30, 31.

Referring again to FIG. 1, the node 34 is connected to an input of an amplifier 35, which is controlled by the lock detection circuit 11 so as to amplify the sampling value at node 34 only if a frequency locking state is detected at the same time at frequency detector block 3. The output of the amplifier 35 is applied to a second input of adder 22 by a second loop filter 36, so as to be superimposed upon the control signal applied to the voltage controlled oscillator 23. The loop filter 36 comprises a low-pass filter, the upper limit frequency of which is higher than that of the first loop filter 12.

While the frequency detector block 3 is not locked, the behaviour of the frequency synthesizer is controlled exclusively by frequency detector block 3.

When the frequency is locked and the dividing ratio N of frequency divider 9 is an integer multiple of the dividing ratio of R of frequency divider 8, the sampling phase detector block 6 samples the output signal of oscillator 23 once per N/R periods, and the sampling phase is the same for each sample. Therefore, the output signal of phase detector block 6 corresponds to the level of the output signal of oscillator 23 at the sampled phase. By superimposing the output signal of phase detector block 6 to the input level of the voltage controlled oscillator 23 in adder 22, the oscillator 23 is slightly detuned, so that the phase of its output signal drifts with the respect to that of the reference signal until a stationary state is reached. The phase shift required for this can obviously be more than 2π, which corresponds to a phase shift of the output signal of frequency divider 9 of 2π/N. At practically relevant values of the dividing ratio N of approximately 100 or more, this implies that by using the phase detector block 6, the phase of the output signal can be controlled at a much higher precision than if only frequency detector block 3 is used, and, on the other hand, the phase shift of the output signal which is caused by phase detector block 6 after the frequency detector block 3 has locked is so small that it is not detected by frequency detector block 3 as a loss of frequency lock.

In another embodiment of the present invention a radio transmitter for use in wireless communication is disclosed. The radio transmitter comprises a frequency synthesizer including a tunable oscillator 23, which provides an output signal of the frequency synthesizer. The frequency synthesizer further comprises a sampling phase detector 6, which receives the output signal from an oscillator 23 and a reference signal, and provides a phase difference signal representative of a phase difference between the output signal and the reference signal for controlling the oscillator. The frequency of the oscillator 23 is further controlled by a frequency difference signal from a frequency detector 3, which is representative of a frequency difference between the output signal and the reference signal.

Alternative embodiments of the radio transmitter include the optional features and implementations as discussed above in connection with the embodiment of the frequency synthesizer.

In yet another embodiment of the present invention a radio receiver for use in wireless communication is disclosed. The radio receiver comprises a frequency synthesizer including a tunable oscillator 23, which provides an output signal of the frequency synthesizer. The frequency synthesizer further comprises a sampling phase detector 6, which receives the output signal from an oscillator 23 and a reference signal, and provides a phase difference signal representative of a phase difference between the output signal and the reference signal for controlling the oscillator. The frequency of the oscillator 23 is further controlled by a frequency difference signal from a frequency detector 3, which is representative of a frequency difference between the output signal and the reference signal.

Alternative embodiments of the radio receiver include the optional features and implementations as discussed above in connection with the embodiment of the frequency synthesizer.

1-27. (canceled)

28. A frequency synthesizer comprising:
a tunable oscillator configured to provide an output signal of the frequency synthesizer;
a frequency detector configured to receive a reference signal and the output signal from the oscillator, and to provide a frequency difference signal representative of a frequency difference between the output signal and the reference signal to control the oscillator;
a sampling phase detector configured to receive the reference signal and the output signal from the oscillator, and to provide a phase difference signal representative of a phase difference between the output signal and the reference signal to control the oscillator; and
wherein the oscillator is further configured to control its frequency according to the frequency difference signal.

29. The frequency synthesizer of claim 28 further comprising an adder configured to receive the phase difference signal and the frequency difference signal, and to provide a summed signal to control the frequency and phase of the oscillator output signal.

30. The frequency synthesizer of claim 28 wherein the frequency detector comprises a lock detection circuit configured to detect when the frequency difference approaches zero, and wherein the sampling phase detector is configured to control the frequency of the oscillator only if the lock detection circuit detects the frequency difference to be zero.

31. The frequency synthesizer of claim 30 wherein the sampling phase detector comprises an amplifier having a gain that is controllable by the lock detection circuit.

32. The frequency synthesizer of claim 28 wherein the frequency detector is further configured to receive the output signal via a first frequency divider.

33. The frequency synthesizer of claim 28 wherein the frequency detector is further configured to receive the reference signal via a second frequency divider.

34. The frequency synthesizer of claim 28 wherein the sampling phase detector is configured to react to a drifting apart of the phases of the output signal and reference signal faster than the frequency detector reacts to the drifting apart of the phases of the output signal and reference signal.

35. The frequency synthesizer of claim 28 wherein the sampling phase detector and the frequency detector each comprise a filter configured to filter the phase difference signal and the frequency difference signal, respectively, and wherein the sampling phase detector filter has a higher upper limit frequency than the frequency detector filter.

36. A radio transmitter comprising:
a frequency synthesizer comprising:
a tunable oscillator configured to provide an output signal of the frequency synthesizer;
a frequency detector configured to:
receive a reference signal, and the output signal from the oscillator; and
provide a frequency difference signal representing a frequency difference between the output signal and the reference signal to control the oscillator;
a sampling phase detector configured to:
receive a reference signal, and the output signal from the oscillator; and
provide a phase difference signal representing a phase difference between the output signal and the reference signal to control the oscillator; and
wherein the oscillator is further configured to control its frequency according to the frequency difference signal.

37. The radio transmitter of claim 36 wherein the frequency synthesizer further comprises an adder configured to receive the phase difference signal and the frequency difference signal, and to provide a summed signal configured to control the frequency and phase of the oscillator output signal.

38. The radio transmitter of claim 36 wherein the frequency detector comprises a lock detection circuit configured to detect when the frequency difference approaches zero, and wherein the sampling phase detector is configured to control the frequency of the oscillator only if the lock detection circuit detects the frequency difference to be zero.

39. The radio transmitter of claim 38 wherein the sampling phase detector further comprises an amplifier having a gain that is controllable by the lock detection circuit.

40. The radio transmitter of claim 36 wherein the frequency detector is further configured to receive the output signal via a first frequency divider.

41. The radio transmitter of claim 36 wherein the frequency detector is further configured to receive the reference signal via a second frequency divider.

42. The radio transmitter of claim 36 wherein the sampling phase detector is configured to react to a drifting apart of the phases of the output signal and reference signal faster than the frequency detector is configured react to the drifting apart of the phases of the output signal and reference signal

43. The radio transmitter of claim 36 wherein each of the sampling phase detector and the frequency detector comprise a filter configured to filter the phase difference signal, and the frequency difference signal, respectively, and wherein the sampling phase detector filter has a higher upper limit frequency than the frequency detector filter.

44. A radio receiver comprising:
a frequency synthesizer comprising:
a tunable oscillator configured to provide an output signal of the frequency synthesizer;
a frequency detector configured to:
receive a reference signal, and the output signal from the oscillator; and
provide a frequency difference signal representing a frequency difference between the output signal and the reference signal to control the oscillator;
a sampling phase detector configured to:
receive a reference signal, and the output signal from the oscillator; and
provide a phase difference signal representing a phase difference between the output signal and the reference signal to control the oscillator; and
wherein the oscillator is further configured to control its frequency according the frequency difference signal.

45. The radio receiver of claim 44 wherein the frequency synthesizer further comprises an adder configured to receive the phase difference signal and the frequency difference signal, and to provide a summed signal to control the frequency and phase of the oscillator output signal.

46. The radio receiver of claim 44 wherein the frequency detector further comprises a lock detection circuit configured to detect when the frequency difference approaches zero, and wherein the sampling phase detector is configured to control the frequency of the oscillator only if the lock detection circuit detects the frequency difference to be zero.

47. The radio receiver of claim 46 wherein the sampling phase detector comprises an amplifier having a gain that is controllable by the lock detection circuit.

48. The radio receiver of claim 44 wherein the frequency detector is further configured to receive the output signal via a first frequency divider.

49. The radio receiver of claim 44 wherein the frequency detector is further configured to receive the reference signal via a second frequency divider.

50. The radio receiver of claim 44 wherein the sampling phase detector is configured to react to a drifting apart of the phases of the output signal and reference signal faster than the frequency detector is configured to react to the drifting apart of the phases of the output signal and reference signal.

51. The radio receiver of claim 44 wherein the sampling phase detector and the frequency detector each comprise a filter to filter the phase difference signal and the frequency difference signal, respectively, and wherein the sampling phase detector filter has a higher upper limit frequency than the frequency detector filter.

52. A method of operating a frequency synthesizer in a wireless communications unit, the method comprising:
generating an output signal of the frequency synthesizer using a tunable oscillator;
receiving the output signal at a sampling phase detector and at a frequency detector;
receiving a reference signal at the sampling phase detector and at the frequency detector;
providing a phase difference signal representing a phase difference between the output signal and the reference signal;
providing a frequency difference signal representing a frequency difference between the output signal and the reference signal; and
controlling a phase and frequency of the oscillator output signal according to the phase difference signal received from the sampling phase detector, and the frequency difference signal received from the frequency detector.

53. The method of claim 52 further comprising adding the phase difference signal and the frequency difference signal, and providing a summed signal to control the frequency and phase of the oscillator output signal.

54. The method of claim 52 further comprising:
detecting when the frequency difference approaches zero using a lock detection circuit of the frequency detector; and
controlling the frequency of the oscillator using the sampling phase detector only if the lock detection circuit detects the frequency difference to be zero.
